(19) United States
(12) Patent Application Publication
(10) Pub. No.: US 2013/0250493 A1
(43) Pub. Date: Sep. 26, 2013

(54) HINGE ASSEMBLY AND ELECTRONIC DEVICE EMPLOYING SAME

(71) Applicants: JING-ZHEN GUO, Shenzhen City (CN); CHAO-YUAN CHENG, Tu-Cheng (TW)

(72) Inventors: JING-ZHEN GUO, Shenzhen City (CN); CHAO-YUAN CHENG, Tu-Cheng (TW)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/481,878

(22) Filed: May 28, 2012

(30) Foreign Application Priority Data
Mar. 23, 2012 (CN) 201220116818.6

(51) Int. Cl. H05K 5/02; E05F 1/12

(52) U.S. Cl. 361/679.01; 16/277

(57) ABSTRACT

A hinge assembly is employed in an electronic device, which includes a first body defining a first receiving groove, a second body defining a second receiving groove opposite to the first receiving groove, and a pivoting member connected between the first body and the second body to form a shaft. The hinge assembly includes a spring member including two securing portions. One of the two securing portions is fixed to the first body in the first receiving groove. The other securing portion is fixed to the second body in the second receiving groove and not collinear with the shaft. When the second body is rotated relative to the first body, the corresponding securing portion fixed to the second body is capable of rotating around the shaft.

### BACKGROUND

1. Technical Field

The present disclosure generally relates to hinge assemblies employed in folding electronic devices.

2. Description of Related Art

Portable electronic devices, such as mobile phones, generally employ hinges in order to rotate or swivel parts of the electronic devices. However, because these hinges are typically bought from a third-party company, the electronic devices must be matched with the hinges, which leads to a high cost and a complex structure.

Therefore, a need exists in the industry to overcome the described problem.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is a schematic view of an electronic device with an exemplary embodiment of the disclosure.

FIG. 2 is a disassembled schematic view of the electronic device shown in FIG. 1.

FIG. 3 is a schematic view of a spring member of a hinge assembly shown in FIG. 1.

FIG. 4 is a sectional view of the electronic device, showing the hinge assembly being connected between a first body and a second body of the electronic device.

FIG. 5 is a schematic view of the electronic device in a closed state with the spring member configured at an original unstretched state.

FIG. 6 is a schematic view of the electronic device, showing the second body rotated an angle relative to the first body with the spring member configured at a maximum stretched state.

FIG. 7 is a schematic view of the electronic device in an open state with the spring member configured at the original unstretched state.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

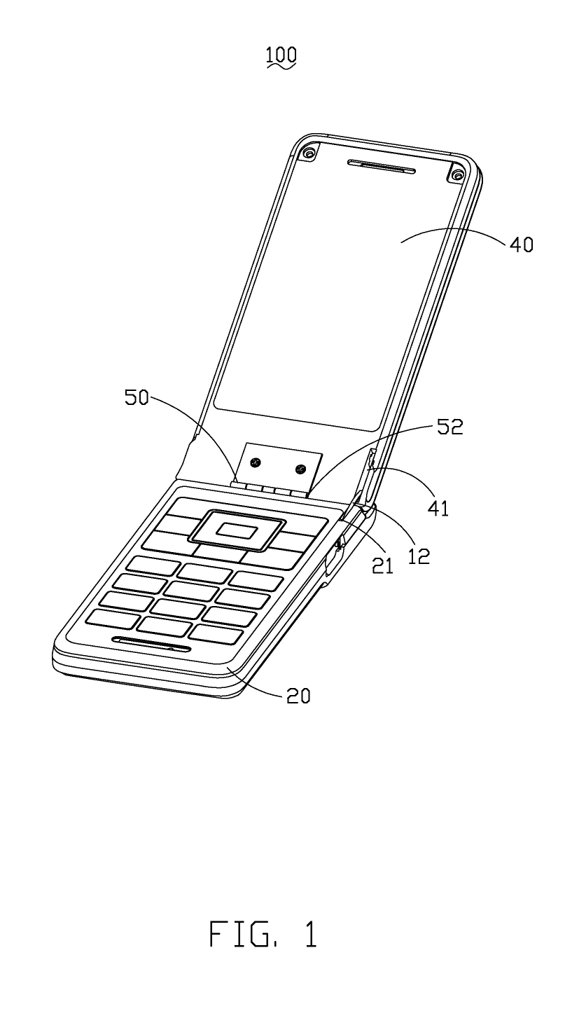

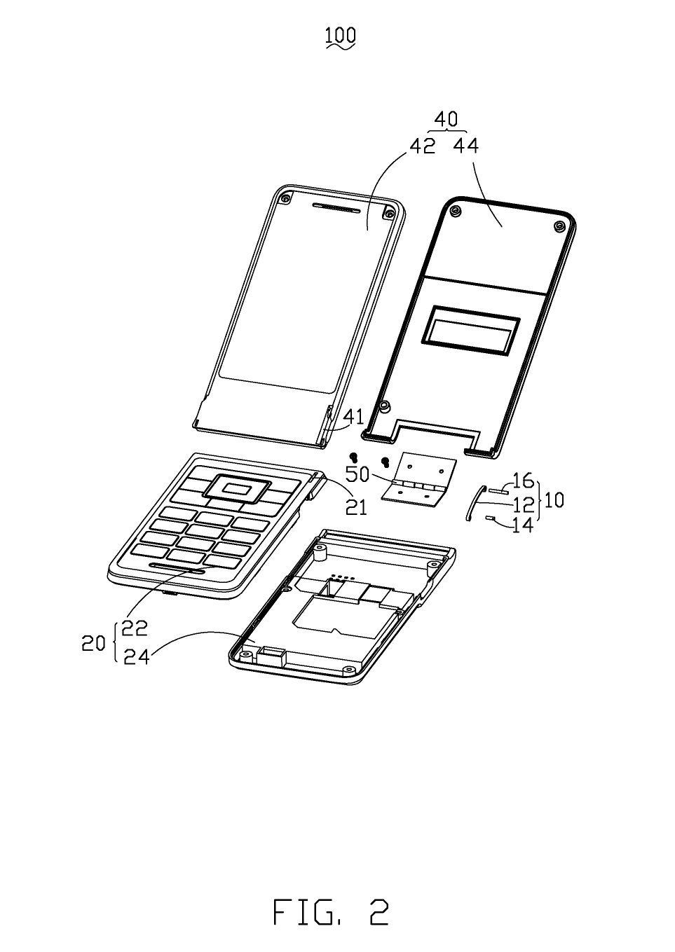

With reference to FIG. 1 and FIG. 2, a hinge assembly 10 is employed in an electronic device 100 comprising a first body 20, and a second body 40 capable of rotating relative to the first body 20. A pivoting member 50 is connected between the first body 20 and the second body 40 to form a shaft 52. The second body 40 rotates about the shaft 52 when the electronic device 100 is opened or closed. That is, the first body 20 and the second body 40 are rotatably connected with each other at ends of the first body 20 and the second body 40 and can be opened at the other ends of the first body 20 and the second body 40. The first body 20 defines a first receiving groove 21 close to the second body 40. The second body 40 defines a second receiving groove 41 close to the first body 20 and opposite to the first receiving groove 21.

In this embodiment, the first receiving groove 21 and the second receiving groove 41 are positioned close to edges of the first body 20 and the second body 40, respectively. The first body 20 comprises a first main part 22 in which the first receiving groove 21 is defined, and a first cover 24 assembled together. The second body 40 comprises a second main part 42 in which the second receiving groove 41 is defined, and a second cover 44 assembled together. The first main part 22 faces the second main part 42, and the first receiving groove 21 and the second receiving groove 41 are located at one corner of the electronic device 100, when the second body 40 is folded on the first body 20.

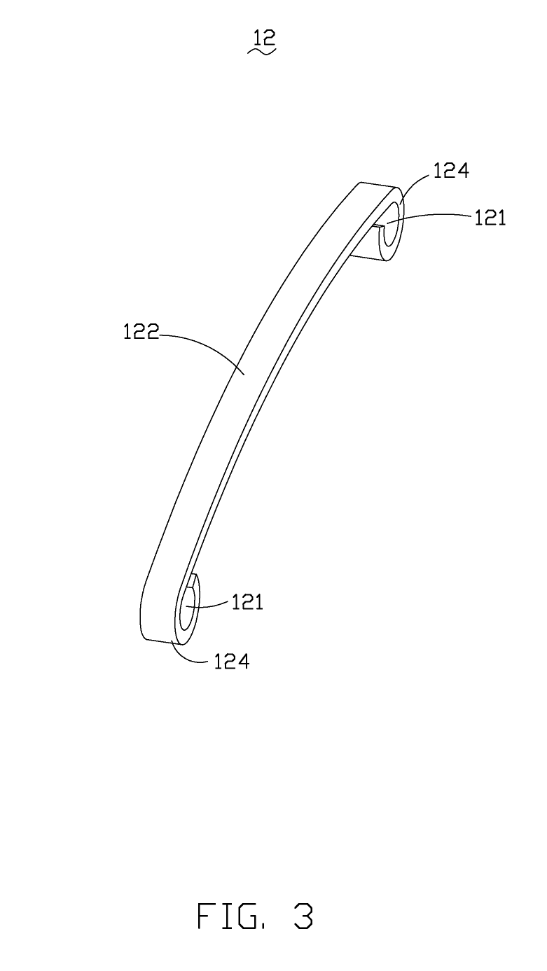

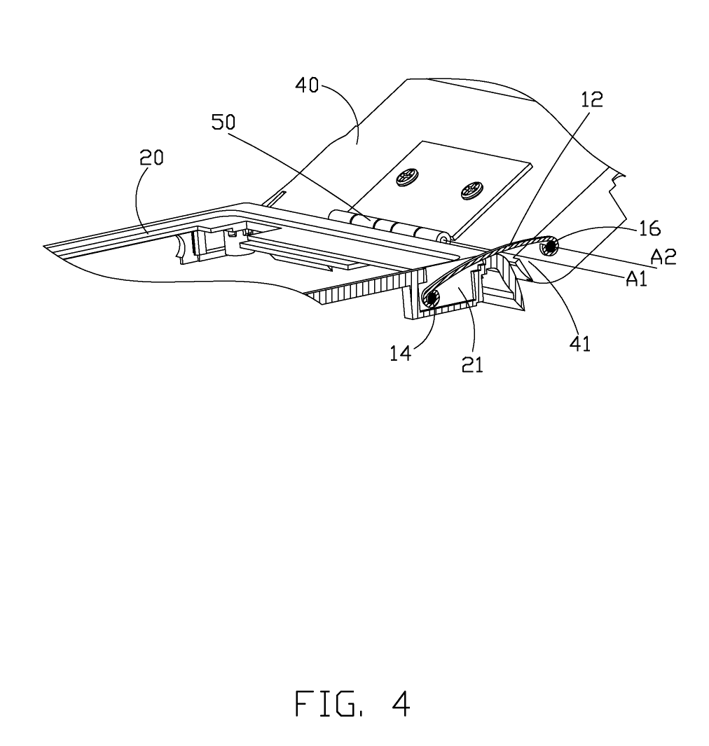

The hinge assembly 10 comprises a spring member 12, a first pin 14 and a second pin 16. The first pin 14 is used to secure one end of the spring member 12 to the first body 20. The second pin 16 is used to secure the other end of the spring member 12 to the second body 40. Referring to FIG. 3 and FIG. 4, the spring member 12 comprises a main body 122 and two securing portions 124 respectively defining a securing hole 121 and located at two opposite ends of the main body 122. The two securing holes 121 of the spring member 12 are used to match with the first pin 14 and the second pin 16. The first pin 14 passes through one of the securing holes 121 to fix the corresponding securing portion 124 of the spring member 12 to the first body 20, similarly, the second pin 16 passes through the other securing hole 121 to fix the corresponding securing portion 124 of the spring member 12 to the second body 40.

In assembly, the two securing portions 124 are respectively received in the first receiving groove 21 and the second receiving groove 41. One of the two securing portions 124, which is fixed to the second body 40, is not collinear with the shaft 52 of the pivoting member 50. In detail, a first axis A1 of the shaft 52 pivoting between the first body 20 and the second body 40 and a second axis A2 of the second pin 16 are not collinear with each other. That is, the first axis A1 and the second axis A2 are non-collinear and parallel with each other.

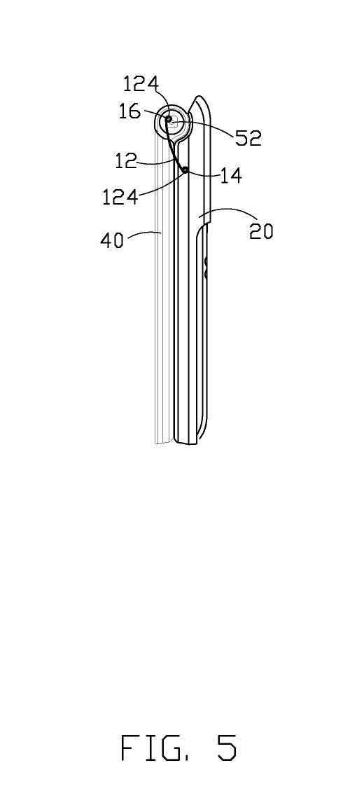

Referring to FIG. 5, the electronic device 100 is configured at a closed state with the spring member 12 at an original unstretched state. When the second body 40 is rotated relative to the first boy 20 around the shaft 52, the second pin 16 is rotated around the shaft 52 together with the second body 40 to make the spring member 12 stretch.

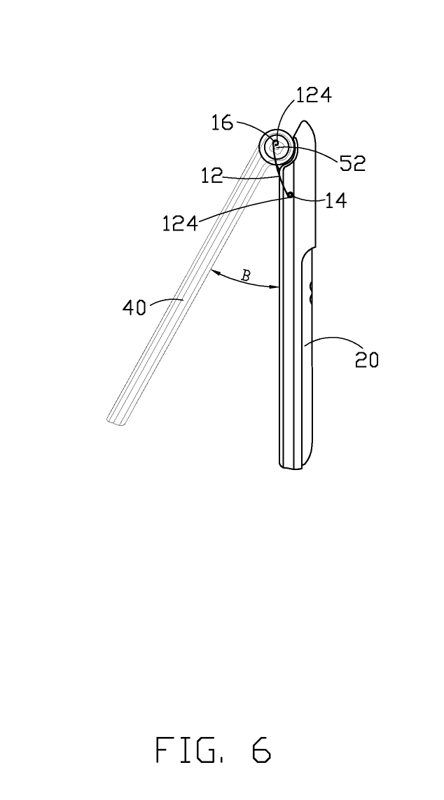

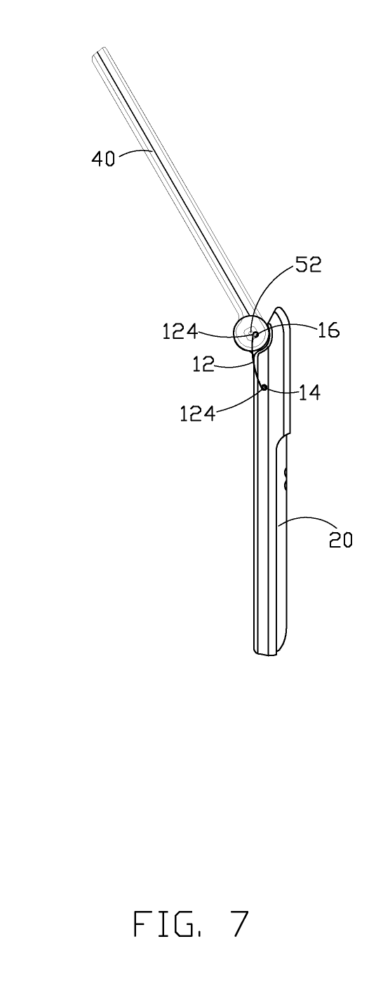

Referring to FIG. 6, the second body 40 is rotated an angle B relative to the first body 20 with the spring member 12 configured at a maximum stretched state. When an angle between the second body 40 and the first body 20 is greater than the angle B, the spring member 12 enables to drive the second body 40 to rotate relative to the first body 20, until the spring member 12 returns to the original unstretched state, shown in FIG. 7, simultaneously, the electronic device 100 is opened. In this embodiment, the angle B is substantially equal to thirty degrees, that is, during rotating the second body 40 relative to the first body 20, the spring member 12 is configured at the maximum stretched state when the angle B is substantially equal to thirty degrees.

In use, the electronic device 100 is swiveled to form the angle B between the first body 20 and the second body 40 by a user's operation, and then the electronic device 100 can be opened just by the elasticity of the spring member 12 without any user's operation. That is, the hinge assembly 10 of the disclosure is capable of driving the second body 40 of the electronic device 100 to rotate relative to the first body 20 just by the elasticity of the spring member 12, which leads to simplification of design of the electronic device 100. Furthermore, the electronic device 100 employing the hinge assembly 10 can rotate or swivel the second body 40 without using standard hinges from a third-party company, which leads to low cost.

Although the features and elements of the present disclosure are described as embodiments in particular combinations, each feature or element can be used alone or in other various combinations within the principles of the present disclosure to the full extent indicated by the broad general meaning of the terms in which the appended claims are expressed.

What is claimed is:

1. A hinge assembly employed in an electronic device, which comprises a first body defining a first receiving groove, a second body defining a second receiving groove opposite to the first receiving groove, and a pivoting member connected between the first body and the second body to form a shaft, the hinge assembly comprising a spring member comprising a main body and two securing portions respectively located at two opposite ends of the main body, one of the two securing portions fixed to the first body in the first receiving groove, the other securing portion fixed to the second body in the second receiving groove and being not collinear with the shaft, wherein when the second body is rotated relative to the first body, the corresponding securing portion fixed to the second body is capable of rotating around the shaft.

2. The hinge assembly as claimed in claim 1, wherein the two securing portions respectively define a securing hole, a first pin passes through one of the securing holes and fix the corresponding securing portion to the first body, and a second pin passes through the other securing hole to fix the corresponding securing portion to the second body.

3. The hinge assembly as claimed in claim 1, wherein the first receiving groove is positioned close to an edge of the first body.

4. The hinge assembly as claimed in claim 1, wherein the first receiving groove and the second receiving groove are located at one corner of the electronic device.

5. The hinge assembly as claimed in claim 1, wherein during rotating the second body relative to the first body, the spring member is configured at a maximum stretched state when an angle between the first body and the second body is substantially equal to thirty degrees.

6. An electronic device, comprising:
a first body, defining a first receiving groove;
a second body, defining a second receiving groove opposite to the first receiving groove;
a pivoting member, connected between the first body and the second body to form a shaft; and
a spring member, comprising two securing portions respectively positioned in the first receiving groove and the second receiving groove and fixed to the first body and the second body;
wherein when the second body is rotated relative to the first body, one of the two securing portions fixed to the second body is capable of rotating around the shaft.

7. The electronic device as claimed as claim 6, wherein the two securing portions respectively define a securing hole, a first pin passes through one of the securing holes and fix the corresponding securing portion to the first body, and a second pin passes through the other securing hole to fix the corresponding securing portion to the second body.

8. The electronic device as claimed in claim 6, wherein the first receiving groove is positioned close to an edge of the first body.

9. The electronic device as claimed in claim 6, wherein the first receiving groove and the second receiving groove are located at one corner of the electronic device.

10. The electronic device as claimed as claim 6, wherein during rotating the second body relative to the first body, the spring member is configured at a maximum stretched state when an angle between the first body and the second body is substantially equal to thirty degrees.

11. An electronic device, comprising:
a first body and a second body rotatably connected with each other via a shaft; and
a hinge assembly, comprising a spring member, a first pin and a second pin, the spring member defining two securing holes, the first pin passing through one of the securing holes and fixed to the first body, and the second pin passing through the other the securing hole and fixed to the second body;
wherein a first axis of the shaft and a second axis of the second pin are not collinear with each other.

12. The electronic device as claimed in claim 11, wherein the first axis and the second axis are parallel with each other.

13. The electronic device as claimed in claim 12, wherein the first body defines a first receiving groove receiving the first pin, and the second body defines a second receiving groove opposite to the first receiving groove and receiving the second pin.

14. The electronic device as claimed in claim 13, wherein the first receiving groove is positioned close to an edge of the first body.

15. The electronic device as claimed in claim 13, wherein the first receiving groove and the second receiving groove are located at one corner of the electronic device.

16. The electronic device as claimed in claim 13, wherein during rotating the second body relative to the first body, the spring member is configured at a maximum stretched state when an angle between the first body and the second body is substantially equal to thirty degrees.
